(19) United States
(12) Patent Application Publication
(10) Pub. No.: US 2015/0027763 A1
(43) Pub. Date: Jan. 29, 2015

(54) INORGANIC FILLER, AND INSULATING RESIN COMPOSITION, INSULATING FILM, PREPREG AND PRINTED CIRCUIT BOARD INCLUDING THE SAME

(71) Applicant: Samsung Electro-Mechanics Co., Ltd., Suwon (KR)

(72) Inventors: Jin Ho HONG, Suwon (KR); Geum Hee Yun, Suwon (KR); Dae Hui Jo, Suwon (KR); Sa Yong Lee, Suwon (KR); Jin Young Kim, Suwon (KR); Keun Yong Lee, Suwon (KR)

(73) Assignee: Samsung Electro-Mechanics Co., Ltd., Suwon (KR)

(21) Appl. No.: 14/143,681

(22) Filed: Dec. 30, 2013

(30) Foreign Application Priority Data
Jul. 29, 2013 (KR) 10-2013-0089589

(51) Int. Cl. H05K 1/03; H05K 1/02; C09C 1/40

(52) U.S. Cl. CPC H05K 1/0373; C09C 1/405; H05K 1/0298; C01P 2004/64; C01P 2004/61; H05K 2201/0209; H05K 2201/068
USPC 174/258; 524/450; 106/483

(57) ABSTRACT

An inorganic filler has a negative coefficient of thermal expansion, and a shell thereon that decreases diffusion of ions contained in the inorganic filler to outside of the shell and organic filler.

### CROSS-REFERENCE TO RELATED APPLICATIONS

This application claims the foreign priority benefit of Korean Patent Application No. 10-2013-0089589, filed on Jul. 29, 2013 in the Korean Intellectual Property Office and entitled “Inorganic Filler, and Insulating Resin Composition, Insulating Film, Prepreg, and Printed Circuit Board Comprising the Same”, the disclosure of which is hereby incorporated by reference in its entirety into this application.

### BACKGROUND

1. Field

Embodiments of the present invention relate to an inorganic filler, and an insulating resin composition, an insulating film, a prepreg, and a printed circuit board including the same.

2. Description of the Related Art

In order to secure reliability in various electronic devices, various conditions such as electrical insulation, thermal stability, and mechanical stability are demanded in insulating layers of printed circuit boards, and the like, used in the various electronic devices. In particular, according to the recent development in electronic devices, the printed circuit board has progressed to have light weight, thin thickness, and small size. In addition, in order to satisfy the demand in lightness and slimness as described above, a wiring of the printed circuit board is more complicated and has high density. As described above, as the electronic devices have light weight and small size, and the wiring thereof has high density, electrical, thermal, and mechanical stability of the insulating layer function as more important factors.

In order to secure the thermal stability and mechanical stability of the insulating layer, a method of impregnating a glass fiber, or the like, into the insulating layer and a method of containing a filler in an insulating resin composition have been mostly used. However, in the case in which the wiring of the printed circuit board is formed in multilayered layers, the insulating layer between the wiring layers should be significantly thin, and therefore, there is a limitation in using the glass fiber having a large volume in the thin insulating layer. Therefore, in general, a build-up insulating layer does not include the glass fiber. Instead, in order to increase the thermal stability and mechanical strength, various kinds of fillers are added to the insulating resin composition for the build-up insulating layer, and in particular, the added content of the filler has gradually increased. However, when the added content of the filler increases, this causes the insulating resin composition to become brittle, such that processability thereof is deteriorated, and in particular, close adhesion between the insulating layer and a circuit pattern layer multilayered thereon is also deteriorated. Therefore, in recent years, a filler having a negative coefficient of thermal expansion is used in order to obtain the thermal stability while minimizing the added content of the filler. A representative example of the filler having the negative coefficient of thermal expansion is a β-eucryptite.

The β-eucryptite is easily prepared and has an economical benefit. After the β-eucryptite is mixed with an inorganic resin such as bismaleimide resin, or the like, to be prepared in a solution state, the prepared solution is used to prepare an insulating film, a prepreg, a resin-coated copper, and the like, and the prepared insulating film, prepreg, and resin-coated copper is used to manufacture the printed circuit board. Meanwhile, in order to effectively use the solution containing the β-eucryptite, the processability of the solution should be stably maintained from the preparation of the solution to the use thereof.

Korean Patent Laid-Open Publication No. KR 10-2003-0059169 discloses the β-eucryptite as one kind of lithiumaluminosilicate, but in the case in which of using the insulating resin composition by mixing the β-eucryptite and the bismaleimide, or the like, the mixed solution has deteriorated stability. That is, a lithium ion contained in the β-eucryptite functions as a catalyst in a curing reaction of a resin performing a radical polymerization reaction such as a bismaleimide resin, and therefore, in the case of preparing and storing a solution by mixing the β-eucryptite with the resin performing the radical polymerization reaction, the lithium ions continuously diffused and released from the β-eucryptite accelerate the resin to be cured, such that the solution gelates, and the processibility thereof is rapidly deteriorated.

Therefore, a method of maintaining a processing stability in the solution prepared by mixing the β-eucryptite with the resin performing the radical polymerization reaction such as the bismaleimide resin in a long-term period has been urgently demanded.

### SUMMARY

In embodiments of the present invention, existing problems according to the prior art may be solved by coating a material that decreases diffusion of ions such as lithium ions from an inorganic filler to the outside on a surface of the inorganic filler having a negative coefficient of thermal expansion, thereby completing the present invention.

Therefore, embodiments of the present invention have been made in an effort to provide an inorganic filler having a core-shell structure including a core formed of the inorganic filler having the negative coefficient of thermal expansion and a shell formed on the core so as to decrease the diffusion of the ions contained in the core to the outside.

In addition, embodiments of present invention have been made in an effort to provide an insulating resin composition containing the inorganic filler having the core-shell structure.

Further, embodiments of present invention have been made in an effort to provide an insulating film prepared by using the insulating resin composition.

In addition, embodiments of present invention have been made in an effort to provide a prepreg prepared by using the insulating resin composition.

Further, embodiments of present invention have been made in an effort to provide a printed circuit board manufactured by using the insulating film or the prepreg.

According to an embodiment of the present invention, there is provided an inorganic filler having a negative coefficient of thermal expansion, the inorganic filler having a shell thereon so as to decrease diffusion of ions contained in the inorganic filler to the outside.

The inorganic filler may contain lithium.

The inorganic filler may include a β-eucryptite represented by the following Chemical Formula 1:

xLi₂O-yAl₂O₃-zSiO₂ [Chemical Formula 1]

in Chemical Formula 1, each x, y and z represents a mixing molar ratio, x and y are each independently 0.9 to 1.1, and z is 1.2 to 2.1.

The shell may include at least one selected from a group consisting of silica, diboron trioxide, alumina, barium sulfate, talc, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

The shell may include silica.

An average diameter of the inorganic filler may be 1 nm to 100 μm.

An average thickness of the shell may be 1 nm to 10 μm.

A silane coupling agent may be coupled onto a surface of the silica.

According to another embodiment of the present invention, there is provided an insulating resin composition including: the inorganic filler as described above; a resin performing a radical polymerization reaction; and a curing agent.

The insulating resin composition may further include a curing accelerator.

The resin may be a bismaleimide resin.

According to another embodiment of the present invention, there is provided an insulating film prepared by coating and semi-curing the insulating resin composition as described above on a substrate.

According to another embodiment of the present invention, there is provided a prepreg prepared by impregnating and drying an organic fiber or an inorganic fiber into a varnish containing the insulating resin composition as described above.

According to another embodiment of the present invention, there is provided a printed circuit board manufactured by multilayering and pressing the insulating film as described above on a substrate having a predetermined circuit pattern or by multilayering and pressing the prepreg as described above on a substrate having a predetermined circuit pattern.

According to another aspect of the present invention, an insulating resin composition includes an organic matrix comprised of a resin; and a plurality of particulate members mixed in the organic matrix. The particulate members have a core-and-shell structure that includes: a core containing an inorganic filler having a negative coefficient of thermal expansion and comprising a β-eucryptite represented by xLi₂O-yAl₂O₃-zSiO₂, where each of x, y and z represents a mixing molar ratio, x and y are each independently 0.9 to 1.1, and z is 1.2 to 2.1; and a shell, formed around the core, that includes at least one selected from a group consisting of silica, diboron trioxide, alumina, barium sulfate, talc, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

Additional aspects and/or advantages will be set forth in part in the description which follows and, in part, will be apparent from the description, or may be learned by practice of the invention.

### BRIEF DESCRIPTION OF THE DRAWINGS

The above and other aspects, features and advantages of the present invention will be more clearly understood from the following detailed description taken in conjunction with the accompanying drawings, in which:

FIG. 1 shows a state in which lithium ions are released from β-eucryptite;

FIG. 2 shows a cross-section of a core-shell structure of an inorganic filler according to an embodiment of the present invention;

FIG. 3 shows a silane coupling agent coupled onto a surface of the inorganic filler according to the embodiment of the present invention; and

FIG. 4 shows a size of the inorganic filler according to the embodiment of the present invention.

### DESCRIPTION OF EMBODIMENTS

The aspects, features and advantages of the present invention will be more clearly clearly understood from the following detailed description of the embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, embodiments of the present invention will be described in detail with reference to the attached drawings.

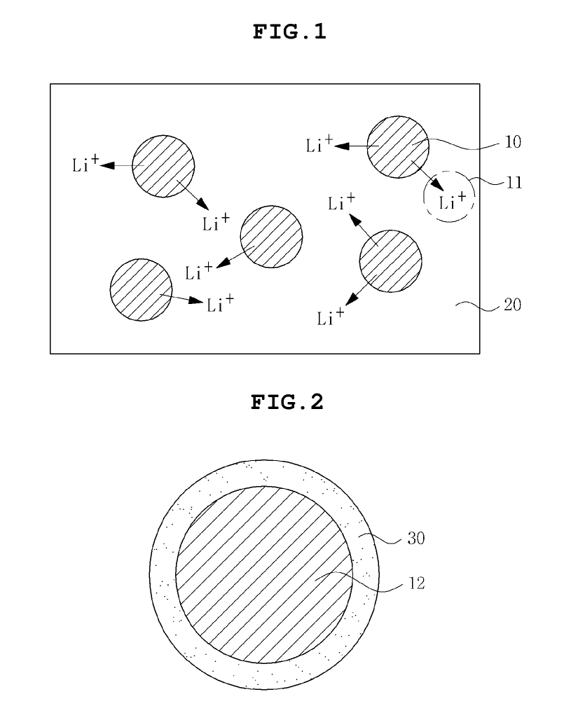

FIG. 1 shows a state in which lithium ions are released from β-eucryptite. Referring to FIG. 1, in a solution obtained by mixing β-eucryptite 10 in an organic matrix 20 containing bismaleimide, or the like, the β-eucryptite may release lithium ions (Li⁺) 11. Meanwhile, the lithium ion may accelerate curing of a resin participating in a radical polymerization reaction such as a bismaleimide resin, or the like, which causes the gelation of the solution and deteriorates processability. In order to solve the above-described problems, the present inventors developed a novel inorganic filler having a structure in which diffusion of the lithium ions is capable of being prevented from the β-eucryptite.

FIG. 2 schematically shows a cross-section of the inorganic filler according to an embodiment of the present invention. Referring to FIG. 2, the filler according to the embodiment of the present invention may basically have a core-shell structure. A core 12 in the core-shell structure is formed of the inorganic filler having a negative coefficient of thermal expansion, and a shell 30 in the core-shell structure is formed of a material capable of decreasing the diffusion of the ions contained in the core to the outside and is formed on the core. The material forming the shell may be the material having a positive coefficient of thermal expansion, but the present invention is not limited thereto, and therefore, any material capable of preventing or decreasing the release (diffusion) of the ions contained in the core formed of the material having the negative coefficient of thermal expansion to the outside may be used. The core-shell structure may generally have a spherical shape, but the present invention is not necessarily limited to the spherical core-shell structure, but the inner core in the chore-shell structure may have various shapes such as an amorphous shape, a hexahedral shape, and a tetrahedral shape. Meanwhile, the shape of the shell in the core-shell structure may be determined depending on the shape of the core, but does not have to be identical to the shape of the core, and therefore, the shell may also have various shapes.

Meanwhile, the inorganic filler having the core-shell structure according to the embodiment of the present invention may contain other materials other than the material having the negative coefficient of thermal expansion in the core, wherein the core may have a combination of two or more fillers. Further, the shell may include a combination of at least one material having the positive coefficient of thermal expansion.

The inorganic filler having the core-shell structure according to the embodiment of the present invention may be formed by a sol-gel reaction.

The novel inorganic filler having the core-shell structure according to the embodiment of the present invention is characterized in that the core is formed of a material containing lithium. Among the materials containing lithium, a representative example is a β-eucryptite, wherein the β-eucryptite is represented by the following Chemical Formula 1:

xLi₂O-yAl₂O₃-zSiO₂ [Chemical Formula 1]

in chemical Formula 1, each x, y and z represents a mixing molar ratio, x and y are each independently 0.9 to 1.1, and z is 1.2 to 2.1.

The β-eucryptite is a crystallized glass formed of Li₂O, Al₂O₃, and SiO₂ components, and in each x, y and z representing the mixing molar ratio of each component, x and y are each independently 0.9 to 1.1, and z is 1.2 to 2.1. In the case in which each x, y, and z has the above-described range, a LiAlSiO₄ crystalline structure having the lowest coefficient of thermal expansion may be effectively synthesized as a crystalline structure of the β-eucryptite. However, when out of the range, since the presence of another phase such as LiAlO₂, Li₂SiO₃, or the like, may be increased and the coefficient of thermal expansion thereof is higher than that of the crystalline structure of the LiAlSiO₄, the coefficient of thermal expansion of the final β-eucryptite ceramic filler is increased, which is not preferred. According to the embodiment of the present invention, in Chemical Formula 1, x may be about 1, y may be about 1, and z may be about 2 in consideration of coefficient of thermal expansion and appearance of the β-eucryptite.

Meanwhile, the shell coated on the core may be a material capable of preventing the the diffusion and the release of the lithium contained in the core. The material generally has a positive coefficient of thermal expansion. The material capable of forming the shell according to the embodiment of the present invention may be any material as long as the release of the lithium present in the core is capable of being physically prevented, and various kinds of inorganic fillers may be used for the shell. Meanwhile, for the present invention, a material not containing the lithium ions is used for the shell. That is, the inorganic filler used for the shell may be selected from a group consisting of silica, diboron trioxide, alumina, barium sulfate, talc, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

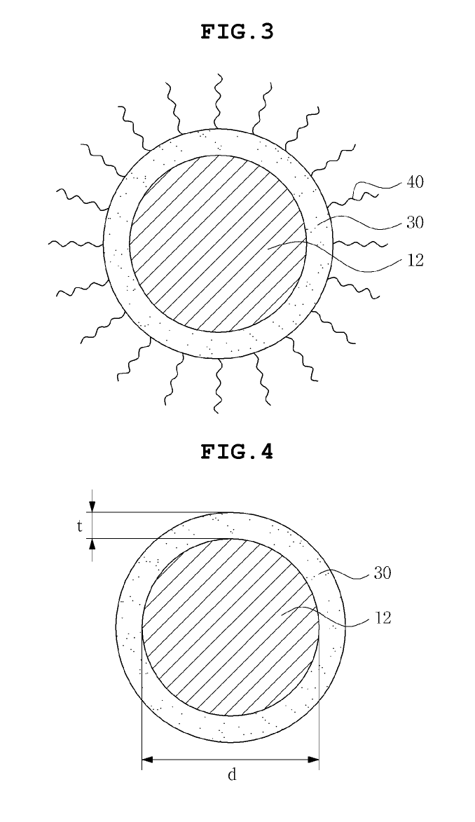

FIG. 3 shows another embodiment of the present invention, in which a silane coupling agent 40 is coupled onto a surface of the shell 30. That is, in the case in which the material for forming the shell is silica, a silane-based coupling agent is coupled onto the surface of the shell formed of the silica, such that coupling strength between the novel filler according to the earlier-discussed embodiment of the present invention and the resin may be increased. The silane coupling agent may be coupled onto the surface of the shell by various methods known in the art.

FIG. 4 shows a size of the inorganic filler having the core-shell structure that may be implemented in embodiments of the present invention. Referring to FIG. 4, the core 12 forming the core-shell structure may have an average diameter d of 1 nm to 100 μm. In the case in which the core has the average diameter less than 1 nm, it is difficult to be dispersed, and in the case in which the core is β-eucryptite, it is difficult to maintain the crystalline structure, such that it has a problem to maintain the negative coefficient of thermal expansion. Meanwhile, in the case in which the core has the average diameter more than 100 μm, it is difficult to be dispersed, and an insulating resin prepared in this case may have an extremely thick thickness due to an increase in a size of the filler. Meanwhile, the shell 30 forming the core-shell structure may have an average thickness t of 1 nm to 10 μm. In the case in which the average thickness of the shell is less than 1 nm, the lithium ions present in the core may not be effectively prevented from being diffused and released to the outside, and in the case in which the average thickness of the shell is more than 10 μm, the shell may be peeled from the core.

The novel inorganic filler having the core-shell structure according to the embodiments of the present invention may be utilized in various fields, and may be representatively used as a component of an insulating resin composition for forming the insulating layer of the printed circuit board.

The insulating resin composition for the printed circuit board may generally contain a contain a filler, a resin, and a curing agent. The filler may be generally an inorganic filler, and a silica is generally used for the filler; however, β-eucryptite having the negative coefficient of thermal expansion is used in the present invention. That is, it is normal that most materials absorb heat, and volume thereof is increased; however, when the β-eucryptite absorbs heat, the volume thereof is decreased. That is, the β-eucryptite has the negative coefficient of thermal expansion. The resin used in the insulating resin composition may be various, and an epoxy resin may be generally used. In embodiments of the present invention, a resin capable of performing the radical polymerization reaction may be used. That is, the novel inorganic filler according to such embodiments of the present invention has an aspect of basically preventing the lithium present in the core from being diffused and released to the outside, which may be obtained by the resin capable of performing the radical polymerization reaction.

Therefore, the resin contained in the insulating resin composition according to embodiments of the present invention is not specifically limited, but may be the resin performing the radical polymerization reaction such as the bismaleimide resin, or the like, in order to achieve aspects of the novel inorganic filler having the core-shell structure. In particular, the bismaleimide resin may have excellent thermal property, mechanical property, or the like. In the case of mixing the bismaleimide resin with the β-eucryptite, processing stability of the resin is significantly deteriorated due to the diffusion and release of the lithium ions in the prior art; however, the filler having the core-shell structure according to the embodiment of the present invention has been developed to solve the problems according to the prior art.

That is, the surface of the β-eucryptite having the negative coefficient of thermal expansion is coated with the silica, or the like, to prevent the lithium ions present in the β-eucryptite from being diffused and released, such that acceleration in curing the bismaleimide which is not preferred may be prevented and the processing stability of the resin may be maintained in a long-term period.

The insulating resin composition according to embodiments of the present invention may contain the curing agent. Various kinds of curing agents may be used depending on the kind of resin contained in the insulating resin composition. In addition, the insulating resin composition according to embodiments of the present invention may further contain a curing accelerator.

The insulating resin composition according to embodiments of the present invention invention may be used to prepare an insulating film or a prepreg. The insulating film may be prepared by coating and curing the insulating resin composition according to such embodiments of the present invention on a predetermined substrate such as polyethyleneterephthalate (PET). The prepared insulating film may be variously utilized, and in general, may be used in order to form a build-up insulating layer of a multilayered printed circuit board. That is, the insulating films are multilayered on the board having a predetermined wiring pattern formed therein, and laminated on the board by vacuum. Meanwhile, the prepreg is prepared by preparing the insulating resin composition according to embodiments of the present invention to be a varnish, impregnating a glass fabric, or the like, into the varnish, and performing a drying process. The prepared prepreg as described above contains the glass fiber therein to have excellent thermal stability and mechanical stability; however, it is difficult to be used in other layers rather than a core layer of the multilayered printed circuit board due to weight and volume occupied by the glass fiber.

Meanwhile, the insulating film or the prepreg prepared by using the insulating resin composition according to embodiments of the present invention may be used to manufacture the printed circuit board. That is, the printed circuit board may be manufactured by multilayering and pressing the insulating film or the prepreg on the board having the predetermined circuit pattern formed therein. The insulating film or the prepreg as described above may serve as an insulating layer of the printed circuit board.

Hereinafter, the present invention will be described in more detail with reference to the following examples and comparative examples; however, it is not limited thereto.

### Comparative Example 1

### Preparation of Powder Having β-Ducryptite Dispersed therein

β-eucryptite of 200 g was put into a mill pot container having ethanol of 400 g, and dispersed for three days by using zirconia beads, thereby preparing a dispersion solution 1. After the β-eucryptite dispersion solution 1 prepared as described above was centrifuged 5 or more times, and dried in an oven in which a temperature of 80° C. was maintained for 1 day, thereby preparing a β-eucryptite filler.

### Comparative Example 2

### Preparation of Bismaleimide Resin Solution Having β-Eucryptite Added thereto

Bismaleimide of 20 g was put into dimethylaceteamide (DMAc) of 80 g, followed by by stirring for 1 hour, to prepare a bismaleimide resin solution in a content of 20 wt %, and the β-eucryptite obtained by Comparative Example 1 of 5 g was added thereto, followed by ultra sonication for 2 hours, to prepare a bismaleimide resin solution having the β-eucryptite powder contained therein.

### EXAMPLE 1

### Preparation of Powder Having β-Eucryptites Dispersed therein, the β-Eucryptite Having Silica Layer Introduced thereinto

Ethanol (more than 99.5%) of 260 g was added to the dispersion solution of 60 g prepared by Comparative Example 1, thereby preparing a dispersion solution 2 having solid content of 6.25 wt %. Tetraethyl orthosilicate (TEOS) of 4 g and an ammonia solution (NH₄OH 25%) of 13 g were added to the dispersion solution 2, followed by stirring at room temperature for 6 hours, to prepare β-eucryptite having a silica layer formed therein. The solution prepared as described above was centrifuged and dried for 5 or more times to prepare a β-eucryptite/silica core-shell powder.

### EXAMPLE 2

### Preparation of Bismaleimide Resin Solution having 3-Eucryptite Added thereto, the β-Eucryptite Having Silica Layer Introduced thereinto

Bismaleimide of 20 g was put into dimethylaceteamide (DMAc) of 80 g, followed by stirring for 1 hour, to prepare a bismaleimide resin solution in a content of 20 wt %. The β-eucryptite/silica core-shell of 5 g prepared by Example 1 was added to the above bismaleimide resin solution in a content of 20 wt %, followed by ultra sonication for 2 hours, to prepare a bismaleimide solution having the β-eucryptite/silica core-shell powder contained therein.

### EXAMPLE 3

### Preparation of Bismaleimide Resin Solution Having β-Eucryptite Added thereto, the β-Eucryptite Having Silica Layer Treated by Vinyltrimethoxy Silane and Introduced thereinto

Vinyltrimethoxy silane of 0.05 g was added to the β-eucryptite/silica core-shell of 5 g prepared by Example 1, followed by stirring for 2 hours. Then, the prepared solution was added to DMAc of 80 g and bismaleimide of 20 g, followed by ultra sonication, to prepare a bismaleimide solution having the β-eucryptite/silica core-shell powder contained therein.

A gelation extent of each solvent depending on time was measured by using each each resin composition prepared by Comparative Example 2 and Example 2, and results thereof were shown in the following Table 1. The gelation extent was indirectly measured by comparing an increased extent viscosity with each other.

TABLE 1

| | Comparative Example 2 | Example 2 |
|---|---|---|
| Day | (Viscosity, cps) | (Viscosity, cps) |
| 1 | 401 | 398 |
| 2 | 521 | 400 |
| 3 | 560 | 402 |
| 4 | 621 | 405 |
| 5 | 763 | 416 |
| 6 | 846 | 420 |
| 7 | 1,006 | 445 |
| 8 | 1,540 | 450 |
| 9 | 2,406 | 465 |
| 10 | 3,510 | 468 |
| 11 | 4,600 | 487 |
| 12 | 6,540 | 490 |
| 13 | 7,004 | 493 |
| 14 | 8,600 | 495 |
| 15 | 8,821 | 498 |
| 16 | 9,864 | 502 |
| 17 | 10,250 | 511 |
| 18 | 12,536 | 516 |
| 19 | 15,045 | 521 |

It may be appreciated from Table 1 above that in Example 2 obtained by mixing the β-eucryptite applied with the silica with the bismaleimide resin according to the embodiment of the present invention, there is little change in viscosity of the solution as time passes. However, it may be appreciated that in Comparative Example 2 obtained by not coating the β-eucryptite with the silica but mixing the β-eucryptite with the bismaleimide resin, the initial viscosity was 401 (cps), but as time passes, the viscosity was rapidly increased, and after 15 days, the viscosity was almost 10,000 (cps). The reason is that the lithium ions present in the β-eucryptite accelerates the bismaleimide resin to be cured and it is evaluated that in the case of coating the β-eucryptite with the silica, or the like, according to an aspect of the present invention, the gelation of the mixing solution may be effectively inhibited.

Meanwhile, in the case of coupling a silane coupling agent on the surface of the silica silica forming the shell according to another aspect of the present invention, evaluation on increase in coupling strength between the filler and the resin, and results thereof were shown in the following Table 2. The coupling strength between the filler and the resin was indirectly measured by coating each of the insulating resin compositions prepared by Examples 2 and 3 on a polyethyleneterephthalate (PET) film, curing the coated compositions to prepare four samples, and measuring mechanical strength of each sample.

TABLE 2

| Sample | Mechanical Strength (GPas) |
|---|---|
| Sample 1 of Example 2 | 15.8 |
| Sample 2 of Example 2 | 16.2 |
| Sample 3 of Example 2 | 16.1 |
| Sample 4 of Example 2 | 15.7 |
| Sample 1 of Example 3 | 21.1 |
| Sample 2 of Example 3 | 20.5 |
| Sample 3 of Example 3 | 19.8 |
| Sample 4 of Example 3 | 20.8 |

Referring to FIG. 2 above, in Example 2 in which the insulating resin solution is prepared by using the filler not coupled with the silane coupling agent onto the surface but having the core-shell structure, the mechanical strength in samples 1 to 4 have the range of 15.7 to 16.2 GPas, which is relatively low, but in Example 3 in which the insulating resin solution is prepared by using the filler coupled with the silane coupling agent onto the surface, the mechanical strength in samples 1 to 4 have the range of 19.8 to 21.1 GPas, which is relatively high. The reason is that the coupling strength between the filler and the bismaleimide resin is increased by the silane coupling agent.

According to the embodiments of the present invention, the filler having the core-shell structure including the β-eucryptite coated with the silica may be provided to prevent the release of the lithium ions contained in the β-eucryptite to the outside, thereby providing stability of the resin performing the radical polymerization reaction, and the silane coupling agent may be coupled onto the surface of the silica to increase the coupling strength between the filler and the organic resin. In addition, the β-eucryptite may be effectively used in the insulating resin composition to significantly decrease the coefficient of thermal expansion of the printed circuit board, or the like.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An inorganic filler having a negative coefficient of thermal expansion, the inorganic filler having a shell thereon so as to decrease diffusion of ions contained in the inorganic filler to outside of the shell and inorganic filler.

2. The inorganic filler as set forth in claim 1, containing lithium.

3. The inorganic filler as set forth in claim 2, further comprising a crystallized glass comprised of Li₂O, Al₂O₃, and SiO₂ components.

4. The inorganic filler as set forth in claim 2, further comprising a β-eucryptite represented by:
xLi₂O-yAl₂O₃-zSiO₂
where each of x, y and z represents a mixing molar ratio, x and y are each independently 0.9 to 1.1, and z is 1.2 to 2.1.

5. The inorganic filler as set forth in claim 2, wherein the shell is made of inorganic material not containing lithium.

6. The inorganic filler as set forth in claims 1, wherein the shell includes at least one selected from a group consisting of silica, diboron trioxide, alumina, barium sulfate, talc, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

7. The inorganic filler as set forth in claim 6, wherein the shell includes silica.

8. The inorganic filler as set forth in claim 1, wherein an average diameter of the inorganic filler is 1 nm to 100 μm.

9. The inorganic filler as set forth in claim 1, wherein an average thickness of the shell is 1 nm to 10 μm.

10. The inorganic filler as set forth in claim 7, wherein a silane coupling agent is coupled onto a surface of the silica.

11. An insulating resin composition comprising:
the inorganic filler as set forth in claims 1;
a resin performing a radical polymerization reaction; and
a curing agent.

12. The insulating resin composition as set forth in claim 11, further comprising a curing accelerator.

13. The insulating resin composition as set forth in claim 11, wherein the resin is a bismaleimide resin.

14. An insulating film comprising the insulating resin composition as set forth in claim 11 having been semi-cured.

15. The insulating film according to claim 14, prepared by coating and semi-curing the insulating resin composition on a substrate.

16. A prepreg comprising:
a varnish containing the insulating resin composition as set forth in claim 11; and
an organic or inorganic fiber impregnated into the varnish.

17. A printed circuit board comprising the insulating film as set forth in claim 14 multilayered and pressed onto a substrate having a predetermined circuit pattern.

18. A printed circuit board comprising the prepreg as set forth in claim 16 multilayered and pressed onto a substrate having a predetermined circuit pattern.

19. An insulating resin composition comprising:
an organic matrix comprised of a resin;
a plurality of particulate members mixed in the organic matrix, each having a core-and-shell structure that includes
a core containing an inorganic filler having a negative coefficient of thermal expansion and comprising a β-eucryptite represented by xLi₂O-yAl₂O₃-zSiO₂, where each of x, y and z represents a mixing molar ratio, x and y are each independently 0.9 to 1.1, and z is 1.2 to 2.1, and
a shell, formed around the core, that includes at least one selected from a group consisting of silica, diboron trioxide, alumina, barium sulfate, talc, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

20. The insulating resin composition as set forth in claim 19, wherein a silane coupling agent is coupled onto a surface of the silica.
